(19) United States
(12) Patent Application Publication
(10) Pub. No.: US 2006/0273390 A1
(43) Pub. Date: Dec. 7, 2006

(54) Gate contact and runners for high density trench MOSFET

(75) Inventors: Fwu-Iuan Hshieh, Saratoga, CA (US); Brian Pratt, San Jose, CA (US)

Correspondence Address: Bo-In Lin, 13445 Mandoli Drive, Los Altos Hills, CA, 94022, US

(73) Assignee: M-MOS Sdn. Bhd.

(21) Appl. No.: 11/182,248

(22) Filed: Jul. 14, 2005

Related U.S. Application Data
(63) Continuation-in-part of application No. 11/147,075, filed on Jun. 6, 2005.

(51) Int. Cl. H01L 29/76

(52) U.S. Cl. 257/331

(57) ABSTRACT

A trenched metal oxide semiconductor field effect transistor (MOSFET) cell that includes a trenched gate surrounded by a source region encompassed in a body region above a drain region disposed on a bottom surface of a substrate. The MOSFET cell further includes a buried trench-poly gate runner electrically contacting to a trench gate of the trenched MOSFET. The buried trench-poly gate runner for functioning as a gate runner to increase gate transmission area and a contact area to a gate contact metal for reducing a gate resistance.

This Patent Application is a Continuation in Part (CIP) Application of a co-pending application Ser. No. 11/147,075 filed by a common Inventor of this Application on Jun. 6, 2005 with a Serial Number. The Disclosures made in that Application is hereby incorporated by reference.

### BACKGROUND OF THE INVENTION

1. Field of the Invention

This invention relates generally to the cell structure, device configuration and fabrication process of power semiconductor devices. More particularly, this invention relates to a novel and improved cell structure, device configuration and improved process for fabricating a trenched semiconductor power device with improved source metal contacts.

2. Description of the Prior Art

Conventional technologies of forming gate contact and gate runners for high density trenched MOSFET devices are faced with a technical difficulty of poor metal step coverage that leads to unreliable electrical contact, and high gate resistance when the cell pitch is shrunken. The technical difficulty is especially pronounced when a metal oxide semiconductor field effect transistor (MOSFET) cell density is increased above 200 million cells per square inch (200M/in²) with the cell pitch reduced to 1.8 um or to even a smaller dimension. The trench width has been reduced below 0.4 um, causing high gate resistance (Rg) as result of less doped poly in trench area. These poor contacts and high gate resistance adversely affect the device performance, and the product reliability is also degraded.

Referring to FIGS. 1A and 1B, for a top view and a side cross sectional view of a conventional MOSFET device 10 formed in a N+ semiconductor substrate 15 with a drain region of a first conductivity type, e.g., an N+ substrate, formed at a bottom surface. The trenched MOSFET cell is formed on top of an epitaxial layer 20 of a first conductivity type, e.g., N− epi-layer that having a lower dopant concentration than the substrate. A body region 25 of a second conductivity type, e.g., a P-body region 25, is formed in the epi-layer 20 and the body region 25 encompasses a source region 30 of the first conductivity type, e.g., N+ source region 30. Each MOSFET cell further includes a polysilicon gate 35 disposed in a trench insulated from the surrounding epi-layer 20 with a gate oxide layer 40. An NSG and BPSG layer 45 insulates the MOSFET from the top and the NSG and BPSG layer 45 further has a gate metal opening to allow a gate contact metal layer 50 to contact the trenched gate 35 and a source-body contact opening to allow a source metal 55 to contact the source regions 30. According to the disclosures made by U.S. Pat. Nos. 5,763,915 and 6,838,722, the gate metal 50 further contacts a wide-trench poly gate contact 60. However, as shown in FIG. 1A, as the gate metal is deposited into the gate metal contact opening, a metal void is formed in the metal layer 50 that causes poor contact to the gate and causes a high on-resistance. The void is generated when the gate metal contact openings has a high aspect ratio due to a large height to width ratio of the contact opening. Furthermore, the gate metal contact is formed with poor step coverage as the contact opening is formed with a stepwise corner and the metal coverage around corners have poor coverage. As shown in a top view of the device 10 in FIG. 1B the gate metal 50 is disposed between the source metal 55 and the gate metal 50 formed as “gate runner to achieve low gate resistance is arranged to contact a gate pad 70 disposed on the right lower corner. The source pad 55 and the gate pad 70 are connected to the leadframe 90 by gold bonding wires 75 and 80 that have diameter not larger than 2 mils.

Referring to FIG. 1C for a MOSFET device 10′ connected to a leadframe 90 through bonded aluminum wire 70′ to the source pads and 80′ to the gate pad 70. As illustrated in FIG. 1C, there are gate-source short at 95 due to the fact that the source pads occupy a large of portion of top surface areas with the gate runners 50 disposed right next to the source pads 55, easily bringing with the source aluminum wires with diameters larger than 10 mil during wire bonding process. Referring to FIG. 1D as a device configuration 10″ to prevent the source-gate short as shown in FIG. 1C. The gate runners are eliminated. However, such configuration has the problem that the gate resistance is increased without the gate runners in the active area.

Therefore, there is still a need in the art of the semiconductor device fabrication, particularly for trenched power MOSFET design and fabrication, to provide a novel cell structure, device configuration and fabrication process that would resolve these difficulties and design limitations. Specifically, it is desirable to maintain low gate resistance and in the meanwhile, it is required to overcome the problems of poor metal step coverage of the gate contact metal especially for gate contact openings that has high aspect ratio and the size of the transistor cells are significantly reduced to increase the cell density of a trenched semiconductor power device.

### SUMMARY OF THE PRESENT INVENTION

It is therefore an object of the present invention to provide new and improved processes to form a reliable gate contact metal layer while maintaining low gate resistance and preventing gate-source short such that the above-discussed technical difficulties may be resolved.

Specifically, it is an object of the present invention to provide a new and improved cell configuration and fabrication process to form a buried trench-poly gate runner and source-body metal contact by applying an oxide etch followed by a silicon etch to open the gate-runner contact trench and a source-body contact trench. The source-body contact trench and the gate runner contact trench then filled with a metal plug deposited by applying a chemical vapor deposition process to assure that reliable source-body contact and gate-runner contact to the trench-poly gate contact are established.

Another aspect of the present invention is to reduce the source-body resistance and gate resistance by forming buried trench-poly gate runner with a source-body trench contact and gate-runner trench contact that are further covered by a thin low-resistance layer with greater contact area to a top thick metal. The thin low-resistance layer forms a good contact to the source-body metal contact plug and the gate-runner trench contact from the top opening of the source-body contact trench and the gate-runner contact trench.

Another aspect of the present invention is to further reduce the gate resistance; an opening is formed in the source metal layer on top of a trenched gate contact plug disposed on top of a trench-poly gate runner. The trenched gate contact plug is formed as Ti/TiN/W plug to contact the buried poly-trench as gate runner for gate resistance reduction, located in the area of the source metal opening.

Briefly, in a preferred embodiment, the present invention discloses a trenched metal oxide semiconductor field effect transistor (MOSFET) device that includes a trenched gate surrounded by a source region encompassed in a body region above a drain region disposed on a bottom surface of a substrate. The MOSFET device further includes a buried trench-poly gate runner electrically contacting to the trench gate buried under an insulation layer for functioning as a gate runner to connected to a gate metal pad through a gate contact plug disposed in a gate contact trench opened through the insulation layer. In a preferred embodiment, the buried trench-poly gate runner having a greater width than the trenched gate. In a preferred embodiment, a portion of the buried trench-poly gate runner having a substantially same width as the trenched gate. In a preferred embodiment, the gate contact trench opened in the insulation layer further extending into a doped poly silicon disposed in the buried trench-poly gate-runner wherein the gate contact trench is further filled with a gate contact metal plug. In a preferred embodiment, the contact metal plug further includes a Ti/TiN barrier layer surrounding a tungsten core as a gate contact metal plug. In a preferred embodiment, the MOSFET device further includes a low resistance conductive layer covering a top surface over the gate contact metal plug for further reducing a gate resistance. In a preferred embodiment, the MOSFET device further includes a source metal covering a top surface of the MOSFET wherein the source metal further having a source metal opening disposed in an area of an active-area gate contact plug filled in the a gate contact trench opened through the insulation layer. In a preferred embodiment the MOSFET device further includes a source-body contact trench opened through the insulation layer into the source and body regions and filled with a source-body contact metal plug. In a preferred embodiment, the source-body contact metal plug further includes a Ti/TiN barrier layer surrounding a tungsten core as a source-body contact metal. In a preferred embodiment, the MOSFET device further includes a thin resistance-reduction conductive layer disposed on a top surface covering the insulation layer and contacting the gate contact metal plug and source-body contact plug whereby the resistance-reduction conductive layer having a greater area than a top surface of the gate contact metal plug and the source-body contact metal plug for reducing the gate resistance and a source-body resistance. In a preferred embodiment, the gate and the source-body contact metal plugs filled in the gate contact trench and the source-body contact trench includes a substantially cylindrical shaped plug. In a preferred embodiment, the MOSFET device further includes a N-channel MOSFET device. In a preferred embodiment, the MOSFET device further includes a P-channel MOSFET device. In a preferred embodiment, the source body contact trench and the gate contact trench further includes an oxide trench formed by an oxide-etch through an oxide layer covering a top surface the MOSFET device. In a preferred embodiment, the source body contact trench and the gate contact trench further includes a silicon trench formed by a silicon-etch after an oxide-etch for extending the source-body contract trench into a silicon substrate and extending the gate contact trench to the buried trench-poly gate runner. In a preferred embodiment, the source body contact trench and the gate contact trench further include a trench opened by a dry oxide and silicon etch whereby a critical dimension (CD) of the source-body contact trench and the gate contact trench is better controlled. In a preferred embodiment, the source body contact trench further includes a trench opened by a dry oxide and silicon etch followed by a wet oxide layer to form irregular shaped trench sidewalls. In a preferred embodiment, the thin resistance-reduction conductive layer includes a titanium (Ti) layer. In a preferred embodiment, the thin resistance-reduction conductive layer includes a titanium nitride (TiN) layer.

This invention further discloses a method for manufacturing a trenched metal oxide semiconductor field effect transistor (MOSFET) device. The method includes a step of forming said MOSFET device with a trenched gate surrounded by a source region encompassed in a body region above a drain region disposed on a bottom surface of a substrate. The method further includes a step of opening a buried trench-poly gate runner electrically contacting to the trench gate and covering the buried trench-poly gate-runner under an insulation layer for functioning as a gate runner. In a preferred embodiment, the method further includes a step of covering the MOSFET device with an insulation layer and applying a contact mask for opening a gate contact trench and opening a sources body contact trench into the source and body regions. In a preferred embodiment, the method further includes a step of filling the gate contact trench and the source-body contact trench with contact metal plugs. In a preferred embodiment, the step of filling the gate contact trench and the source-body contact trench with contact metal plug further comprising a step of filling the contact trenches with a Ti/TiN barrier layer surrounding a tungsten core as a contact metal plug.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a side cross-sectional view of a conventional MOSFET device.

FIGS. 1B to 1D are three alternate top views of a conventional MOSFET device.

FIGS. 2A and 2B are two top views for a MOSFET device with buried trench-poly gate runner of this invention and FIGS. 2C and 2D are two cross sectional views of the MOSFET device of FIGS. 2A and 2B.

FIG. 2E is a top view of the MOSFET device of FIG. 2A with connections to a lead frame.

FIGS. 3A and 3B are two top views for an alternate MOSFET device with buried trench-poly gate runner of this invention and FIGS. 3C and 3D are two cross sectional views of the MOSFET device of FIGS. 3A and 3B.

FIGS. 3E and 3F is a top view and a side cross sectional views respectively of the MOSFET device of FIG. 3A with connections to a lead frame.

FIG. 4 is a top view of another MOSFET device with buried trench-poly gate runner of this invention.

FIGS. 5A to 5E are a serial of side cross sectional views for showing the processing steps for fabricating a MOSFET device as shown in FIGS. 2A to 2E.

FIGS. 5D′ to 5E′ are two side cross sectional views for showing the processing steps for fabricating a MOSFET device as shown in FIGS. 3A to 3E and FIG. 4.

### DETAILED DESCRIPTION OF THE PREFERRED EMBODIMENT

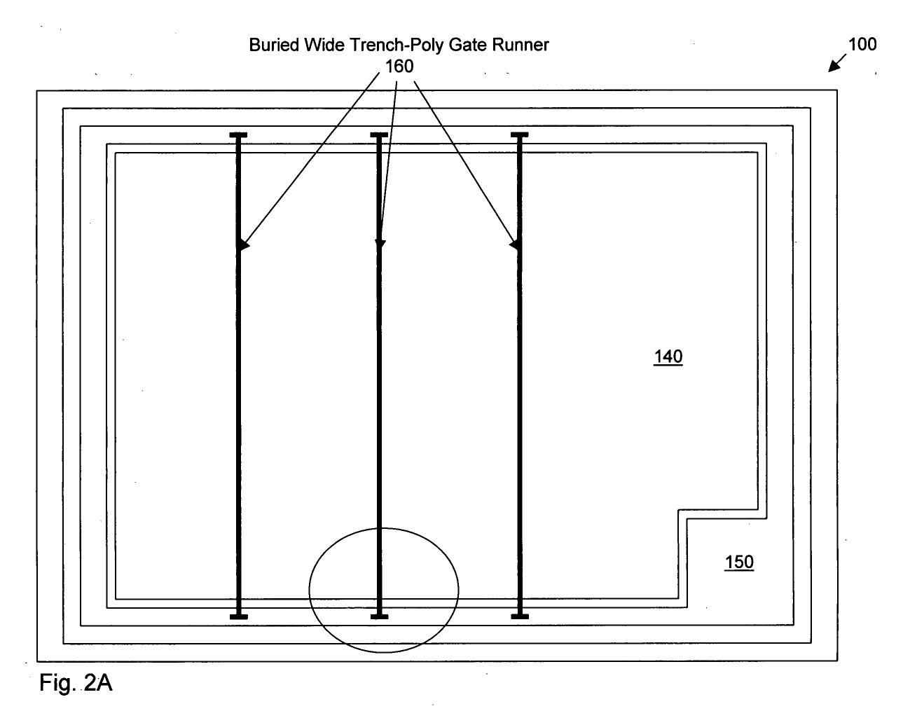

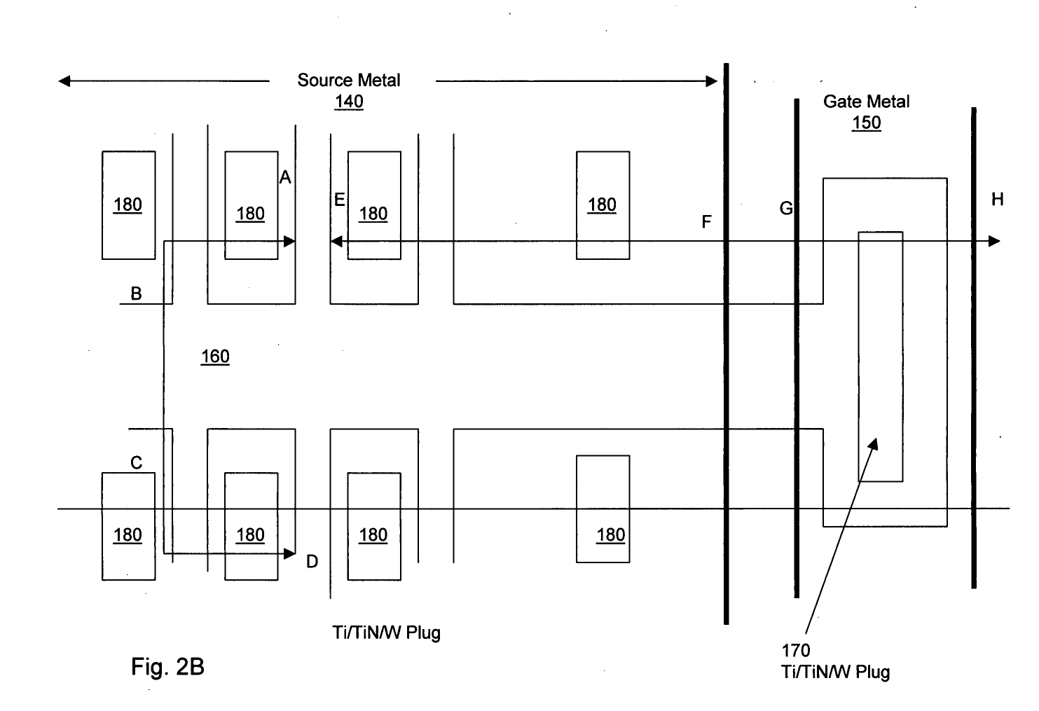

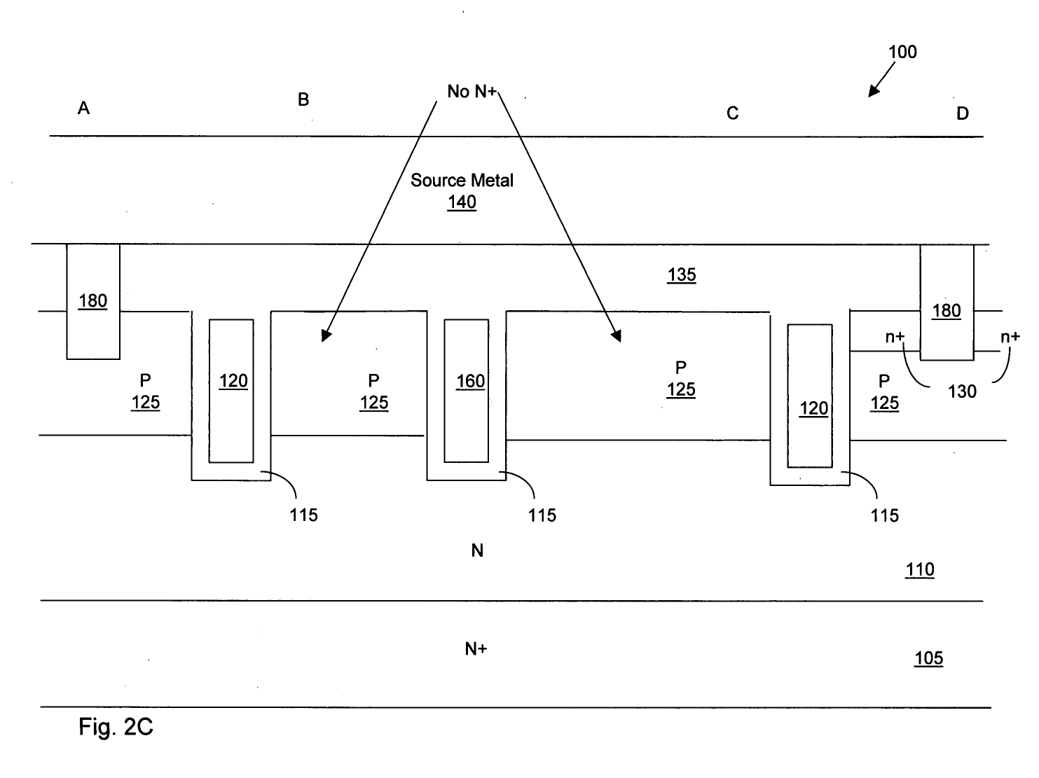

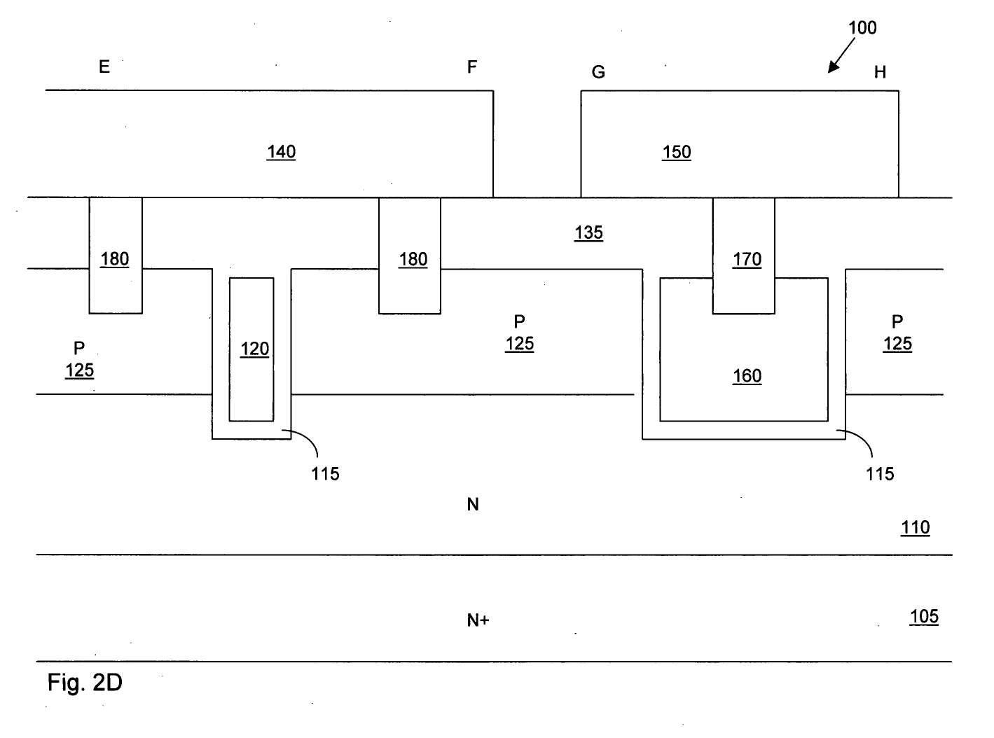

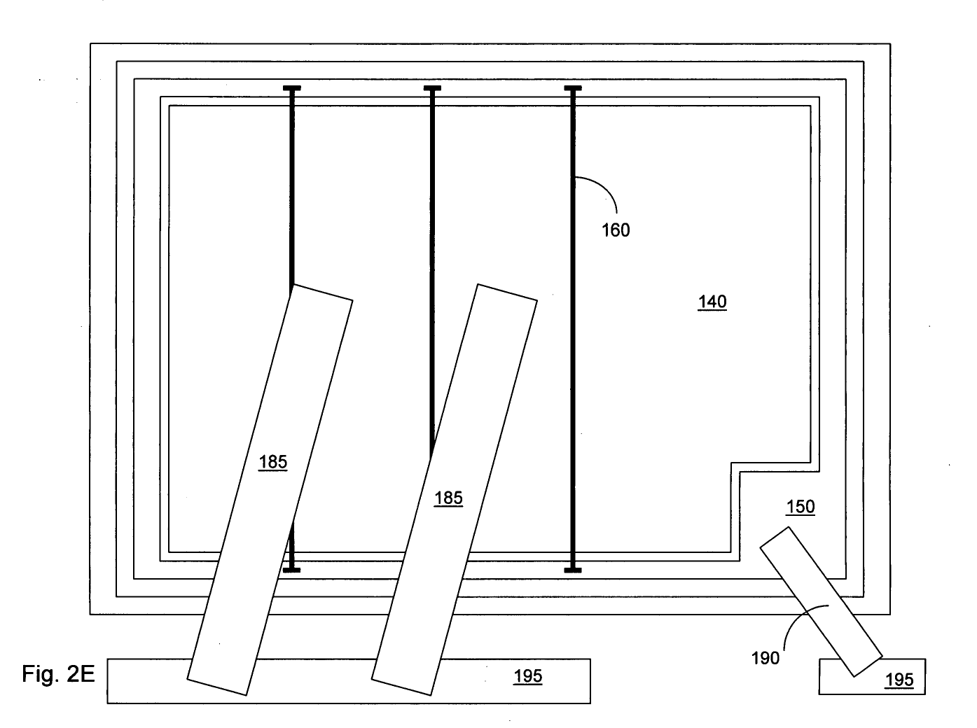

Please refer to FIGS. 2A to 2E for a first preferred embodiment of this invention where a metal oxide semiconductor field effect transistor (MOSFET) device 100 is supported on a substrate 105 formed with an epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 125. The top surface of the semiconductor substrate extending over the top of the trenched gate, the P body regions 125 and the source regions 130 are covered with a NSG and a BPSG protective layers 135. A source metal layer 140 and gate metal layer 150 are formed on top of the protective insulation layer 135.

For the purpose of improving the gate metal contact to the narrow trenched gate 120, a buried poly-trench 160 is formed and filled with polysilicon. A gate contact opening filled with Ti/TiN/W plug 170 is formed in the protective insulation layer 135 and the buried poly-trench to contact the gate metal 150. A buried poly trench 160 is also form as gate runner to reduce gate resistance as result of narrow trench gate 120. Furthermore, for the purpose of improving source metal layer 140 to contact the source regions 130, a plurality of trenched source contact filled with a tungsten plug 180 is formed in the protective insulation layer 135. These tungsten plugs 180 are surrounded by a barrier layer Ti/TiN (not specifically shown). The contact trenches are opened through the NSG-BPSG protective layers 135 to contact the source regions 130 and the P-body 125. Additional details of the structure and configurations of the source contact trenches and plugs are further disclosed in co-pending application and will not be described here. FIG. 2E is a top view showing the source metal 140 is connected to a lead frame 195 with aluminum wire 185 and the gate metal 150 is connected to the lead frame with aluminum wire 190. Since the buried trench poly gate runner 160 are insulated and buried under the source metal 140, there is no concern for source-gate short with the gate runners now formed as buried trench poly 160 as shown in FIGS. 2A to 2D.

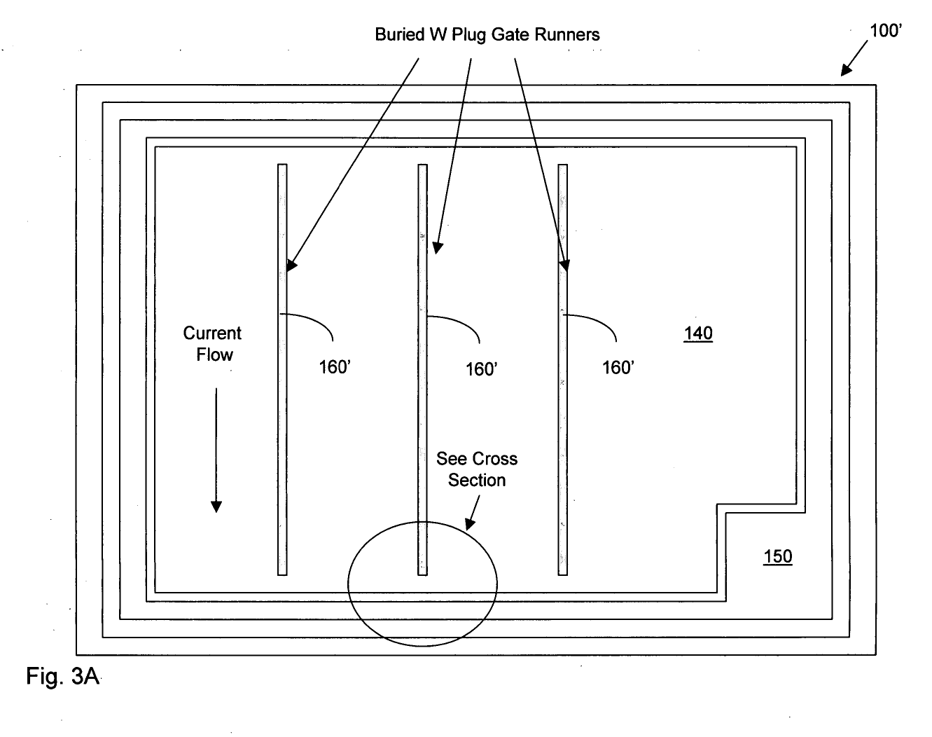

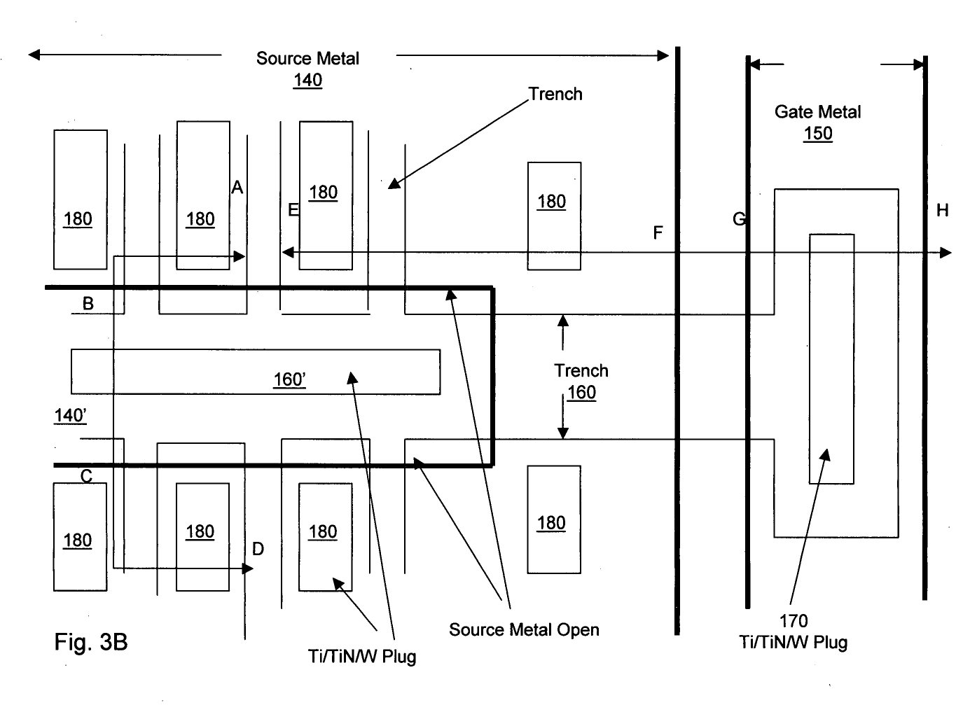

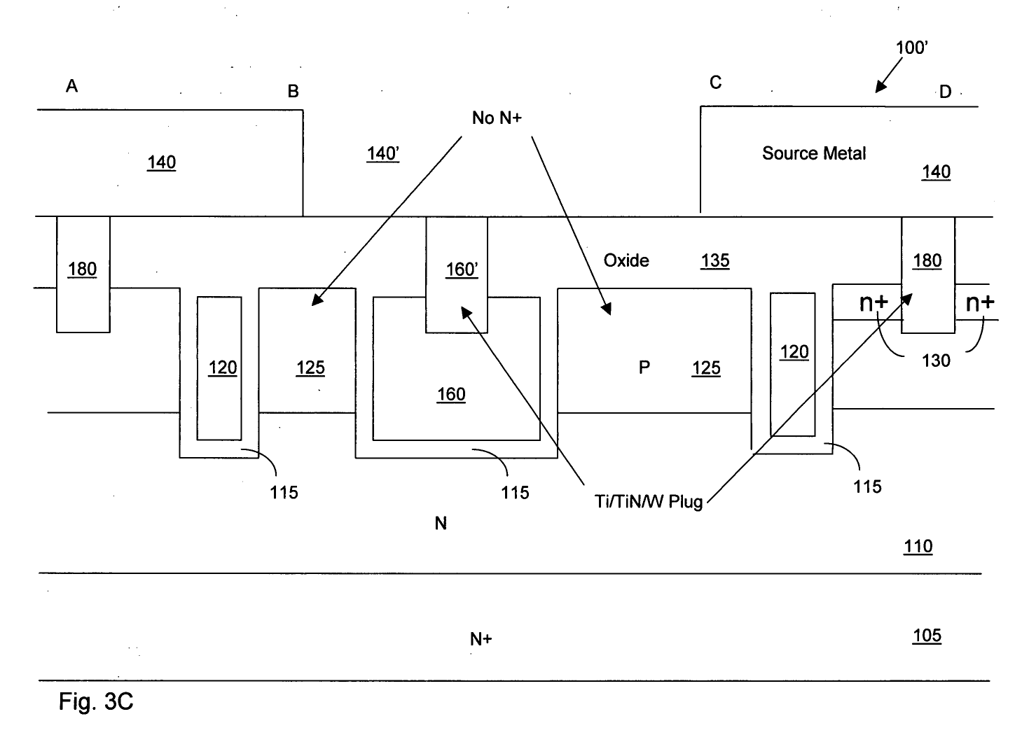

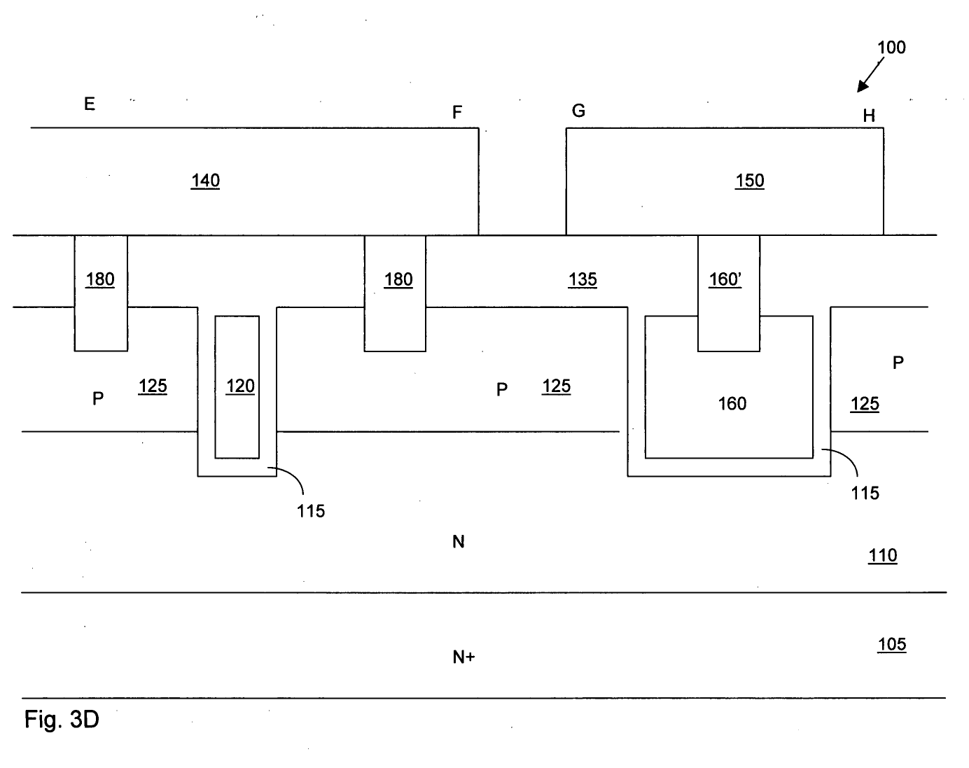

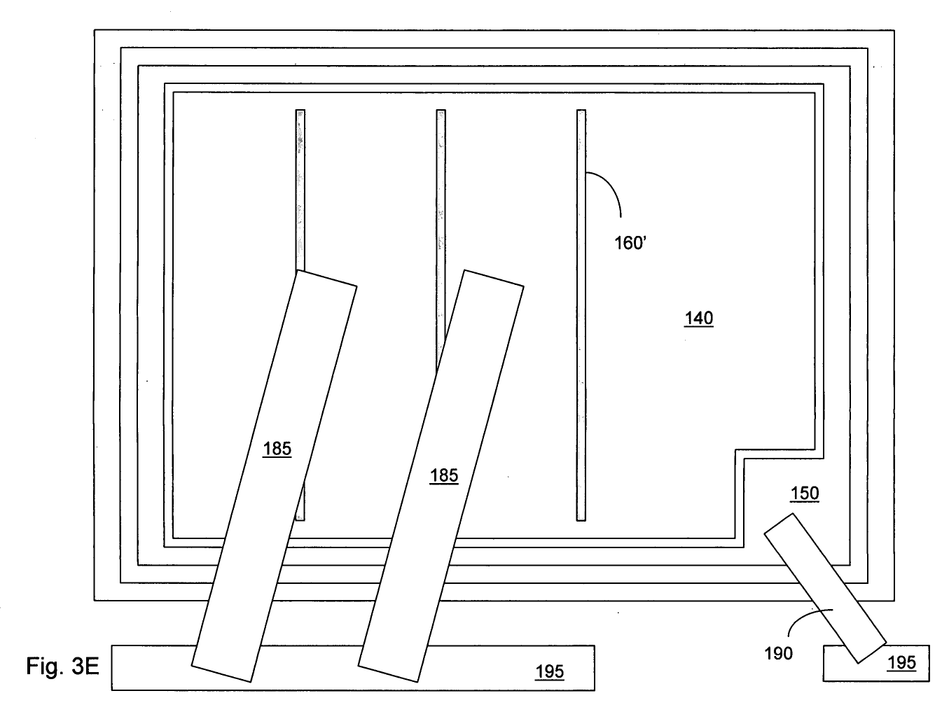

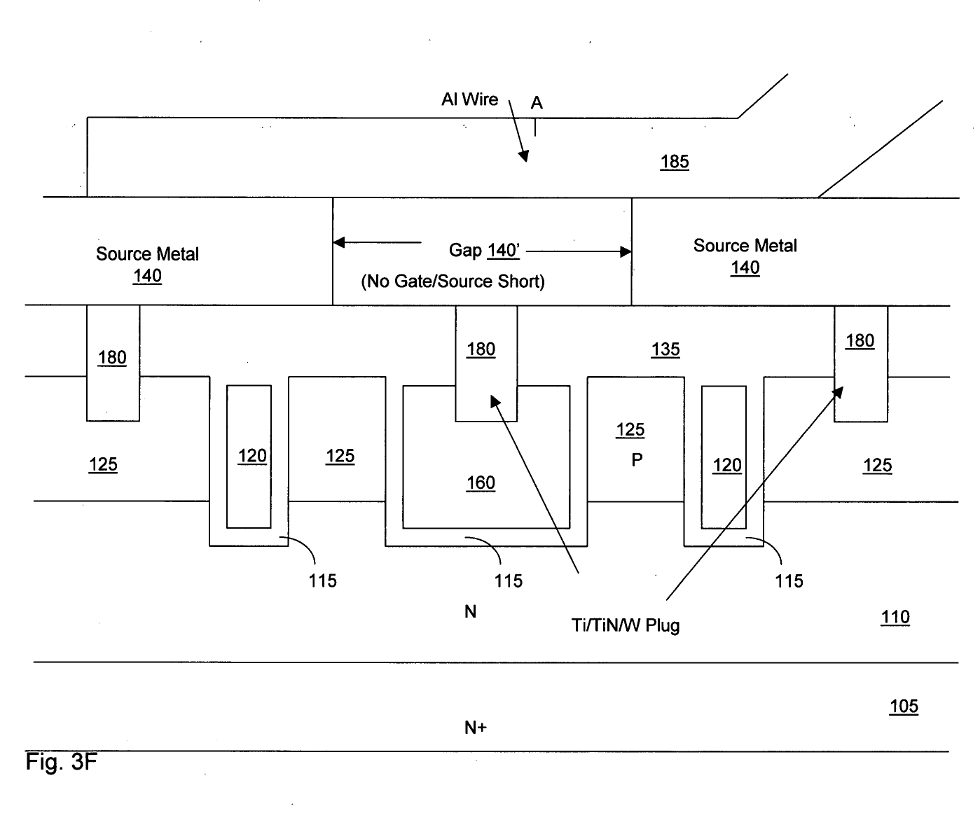

Referring to FIGS. 3A to 3D for an alternate MOSFET 100′ device of this invention. The MOSFET device 100′ is similar to MOSFET device 100 shown in FIG. 2A to 2D. The MOSFET device 100′ is supported on a substrate 105 formed with an epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 125. The top surface of the semiconductor substrate extending over the top of the trenched gate, the P body regions 125 and the source regions 130 are covered with a NSG and a BPSG protective layers 135. A source metal layer 140 and gate metal layer 150 are formed on top of the protective insulation layer 135.

For the purpose of improving the gate metal contact to the gate 120, a buried poly-trench 160 is formed and filled with polysilicon. A gate contact opening filled with Ti/TiN/W plug 160′ is formed in the protective insulation layer 135 and the buried poly-trench 160 to contact the gate metal 150. Furthermore, for the purpose of improving source metal layer 140 to contact the source regions 130, a plurality of trenched source contact filled with a tungsten plug 180 is formed in the protective insulation layer 135. These tungsten plugs 180 are surrounded by a barrier layer Ti/TiN (not specifically shown). The contact trenches are opened through the NSG-BPSG protective layers 135 to contact the source regions 130 and the P-body 125. For the purpose of reducing gate resistance, an opening 140′ is formed in the source metal layer 140. A plug 160′ of Ti/TiN/W is formed in the buried poly-trench 160 as gate runner for gate resistance reduction, located in the area of the source metal opening 140′. FIGS. 3E and 3F is a top view and a side cross sectional view showing the source metal 140 connected to a lead frame 195 with aluminum wire 185 and the gate metal 150 is connected to the lead frame with aluminum wire 190. Since the buried trench poly gate runner 160′ now formed as the Ti/TiN/W plug 160′ are disposed at distance away from the aluminum wire 185 in the source metal opening 140′, there is no concern for source-gate short. As shown in FIG. 3A, the direction of current flow is along a direction parallel to the gate metal contact plug 160′.

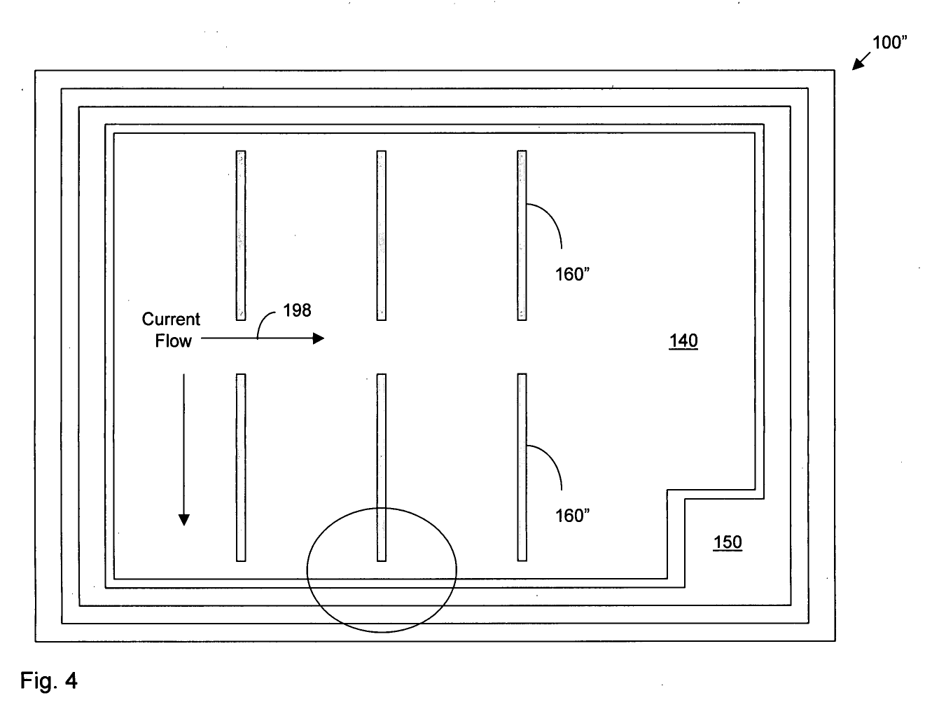

FIG. 4 shows another MOSFET device 100″ with similar device configuration as that shown in FIGS. 3A to 3E. The MOSFET device 100″ also has a gate contact plug 160″ composed of tungsten surrounded by conductive barrier layer, i.e., Ti/TiN/W plug as gate runners. The only difference is that the gate contact plug 160″ formed on top of the buried poly trenches 160 do not extend over the entire length of the device 100″ and has a opening to allow the current to flow both parallel to the direction of the gate contact plugs 160″ and along a perpendicular direction 198 through the opening areas of the gate contact plug 160″ substantially provided at a central portion of the device 100″.

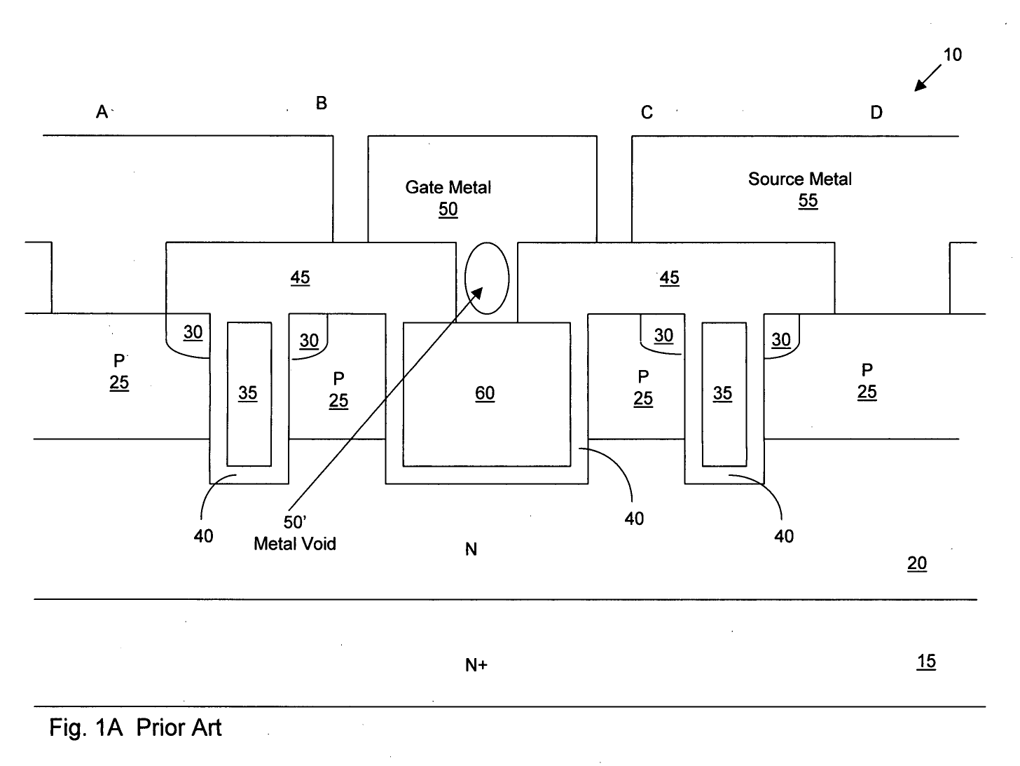

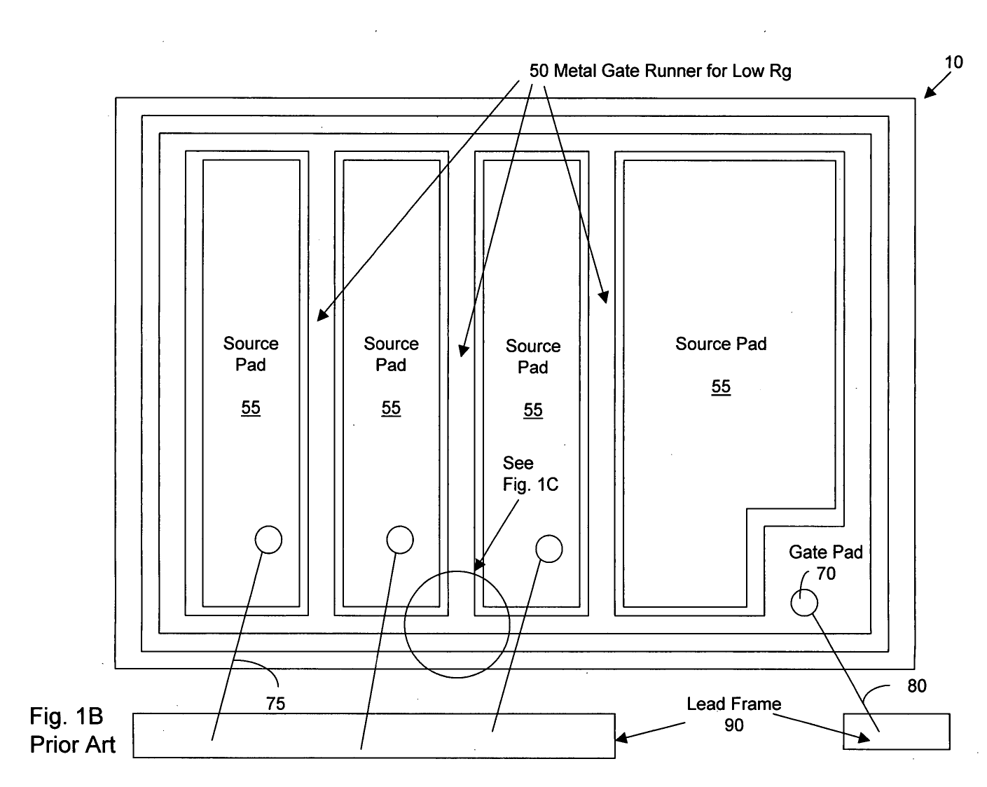

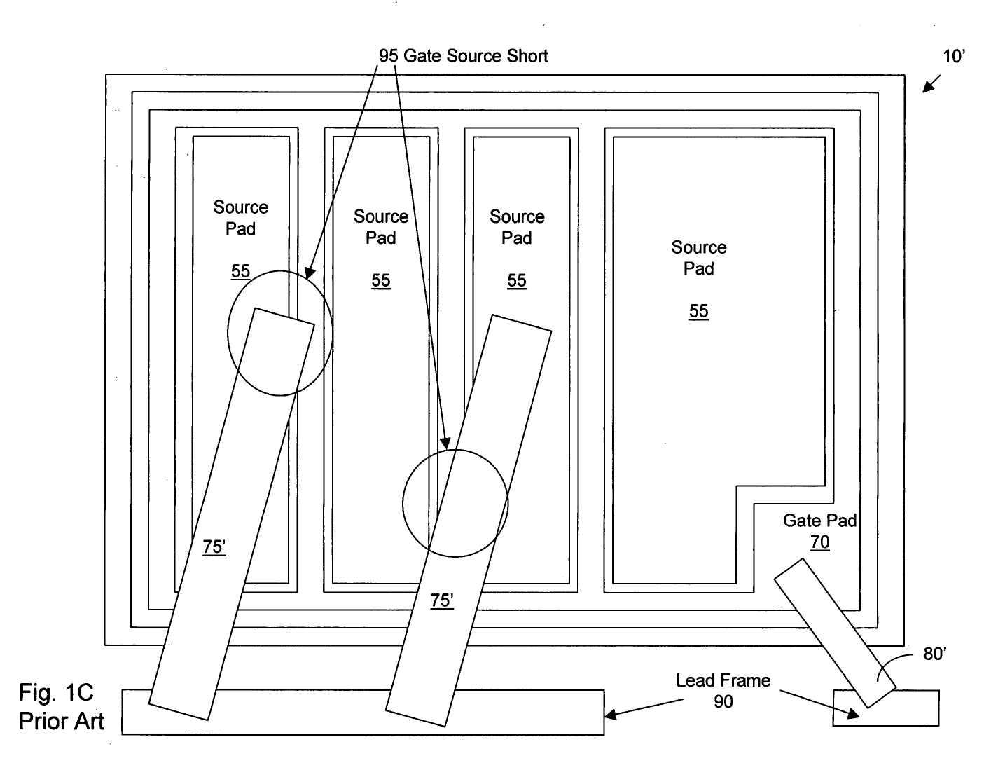

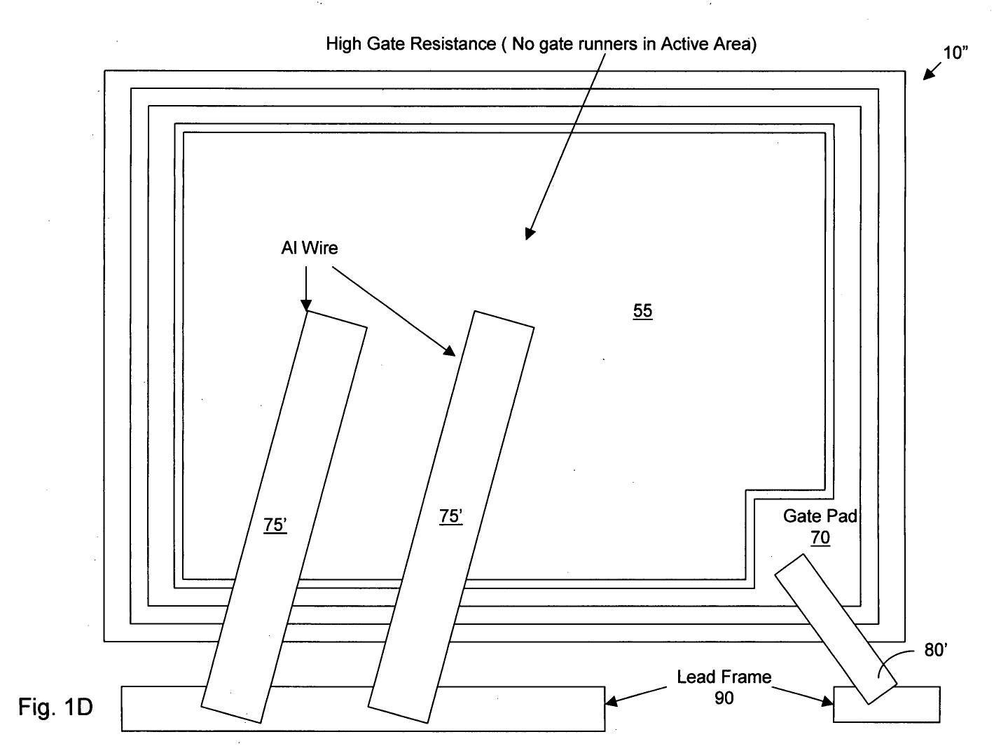

There are significant differences between the conventional gate runners and gate contact and the gate runners and gate contacts as disclosed in this invention. As shown in FIG. 1A the gate contact 50′ is opened in the oxide layer 45. In contrast, the gate contact shown in FIG. 2D filled with tungsten contact plug 170 is opened through the oxide layer 135 and also the doped polysilicon 160 in the trench serving the function as gate runners. Better electrical contacts are established. The gate contact 50's as shown in FIG. 1A is filled with a single metal such as aluminum. The aluminum metal is sputtered into the gate contact openings that often develops a void 50″ while the gate contacts of this invention is tungsten plug. The tungsten plug is formed with the chemical vapor deposition (CVD) process and the chemical vapor has much better filling characteristics to fill the narrow and deep contact openings without development of void. The CVD process is suitable for process of circuits with critical dimension (CD) less than 0.4 micrometer (μms) in the semiconductor industries. As shown in FIG. 1A, the gate runner 60 for direct contact with a gate contact metal 50′ to the gate runners 50 requires a trench width greater than the gate trenches 35. In contrast, in this invention, the buried trench-poly gate runner 160 in the active areas as shown in FIG. 2C may be opened with a trench width same as a gate trench 120. It is only required that the gate trench-poly gate runner 160 for contacting the trenched gate-contact plug 170 to the gate metal 150 to have greater width. Therefore, in one preferred embodiment, at least one of the trench-poly gate runners 160 has a same trench width same as the trenched gate 2C.

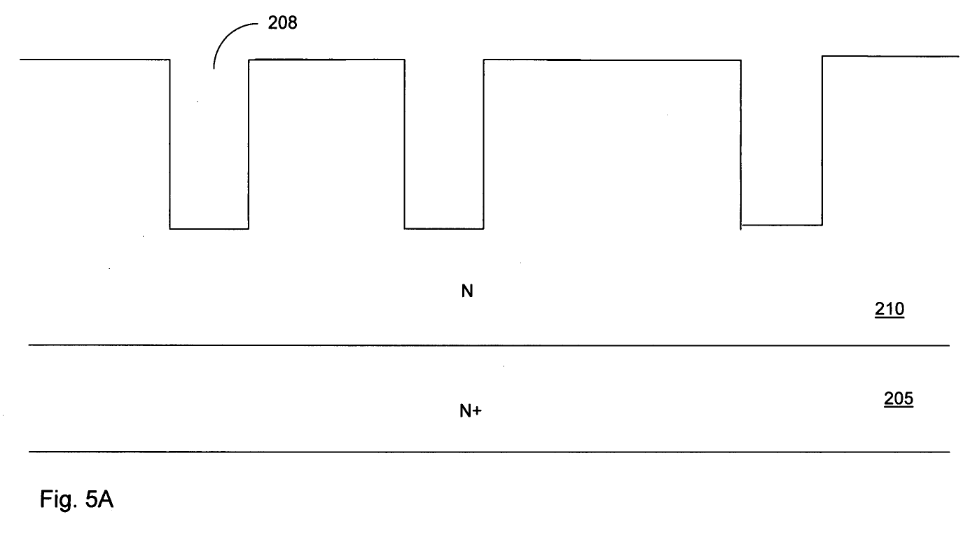

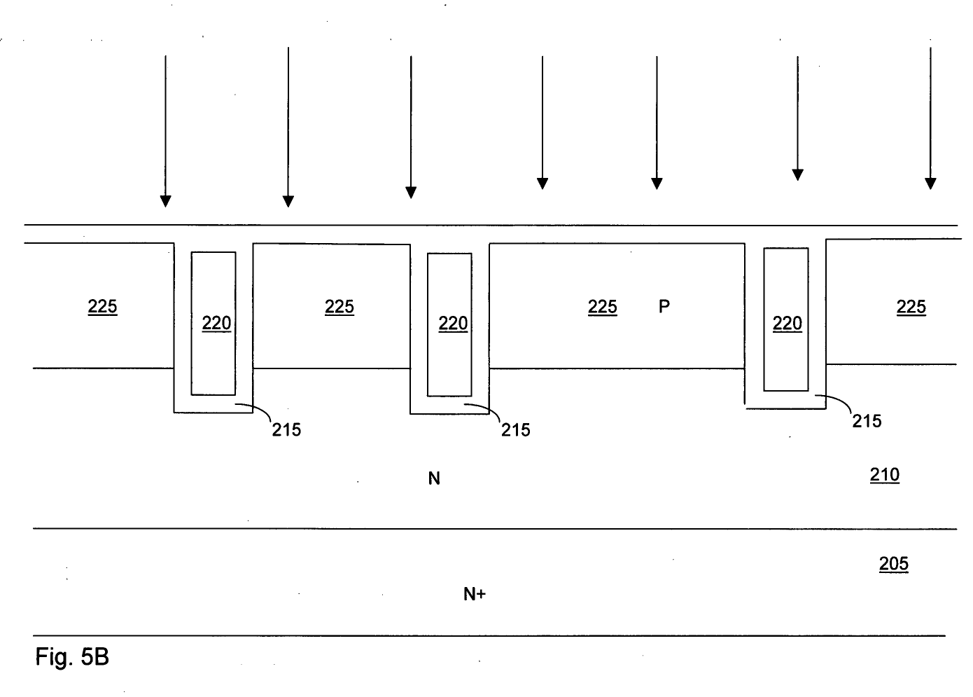

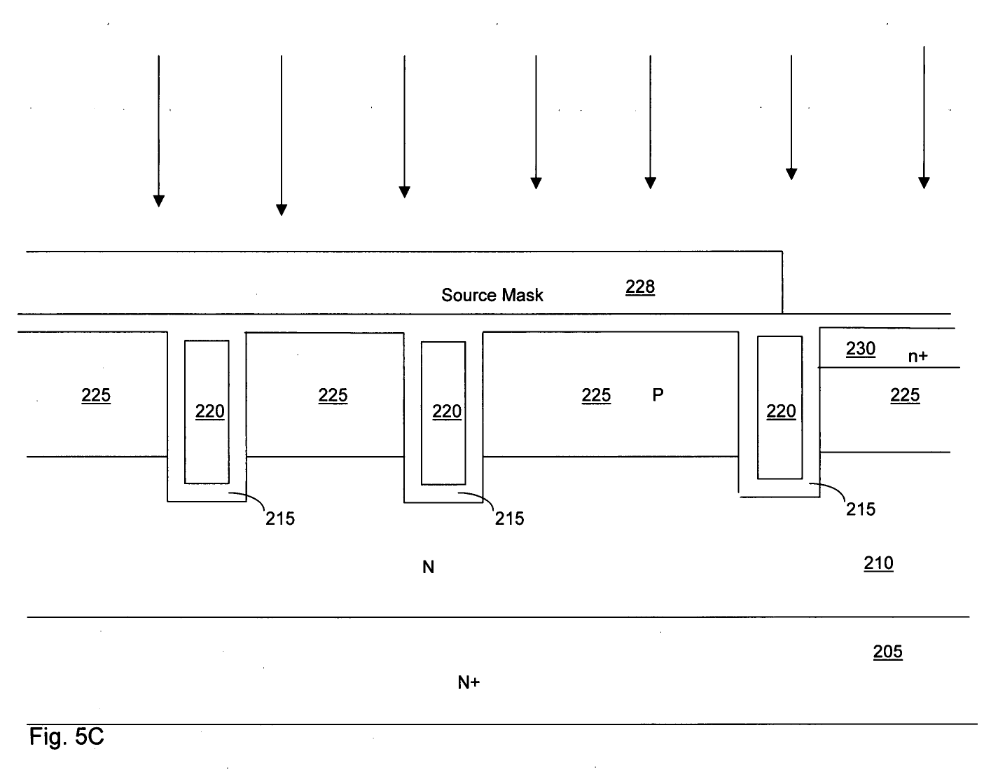

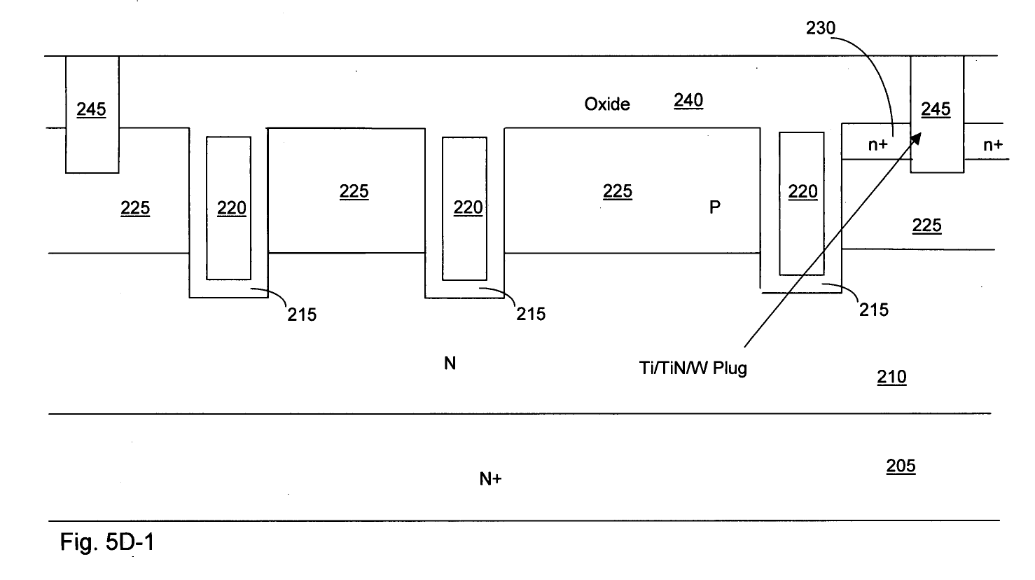

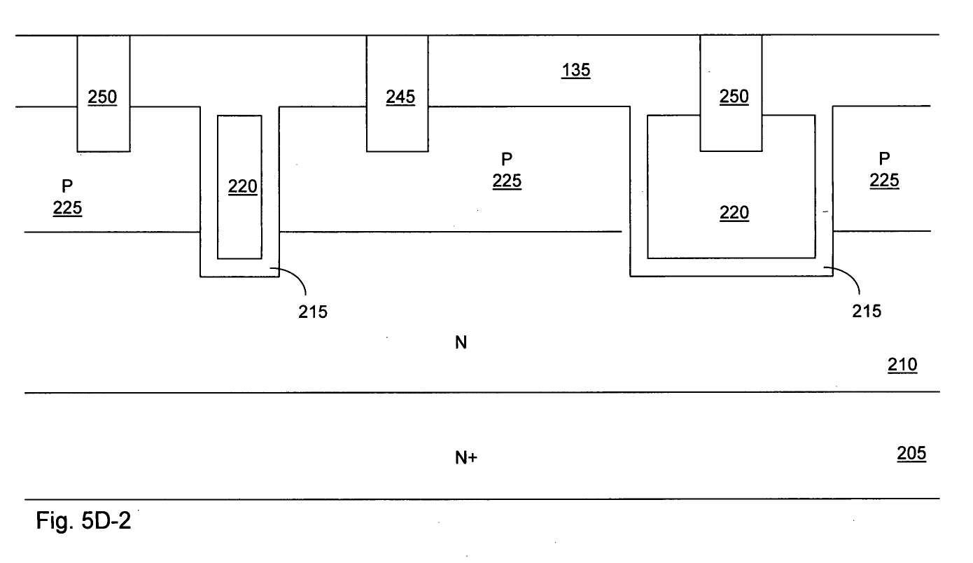

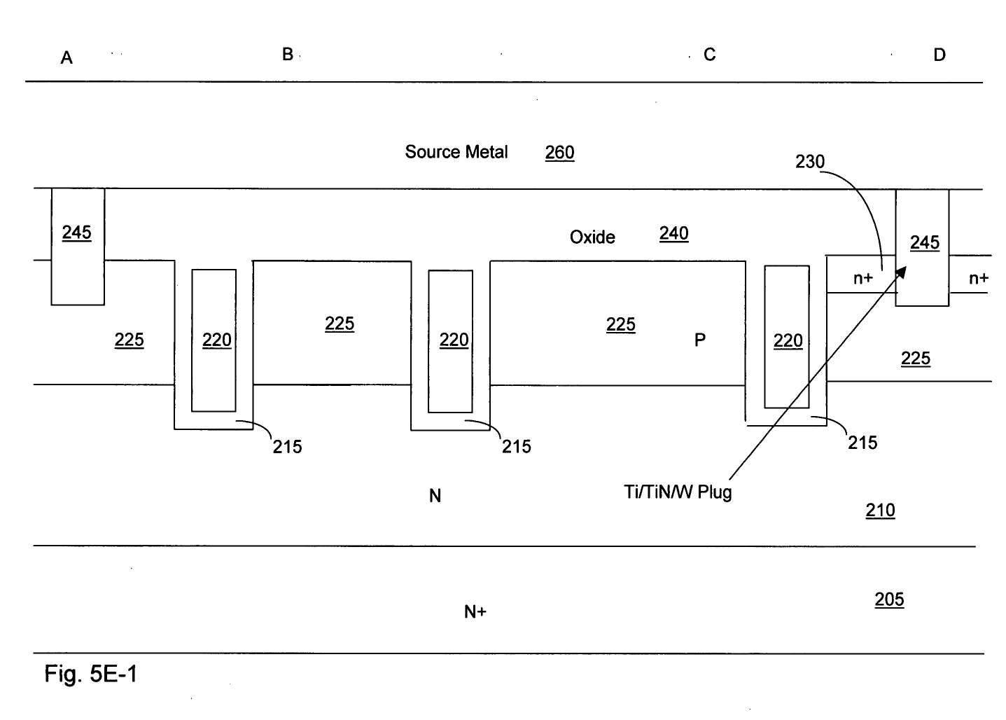

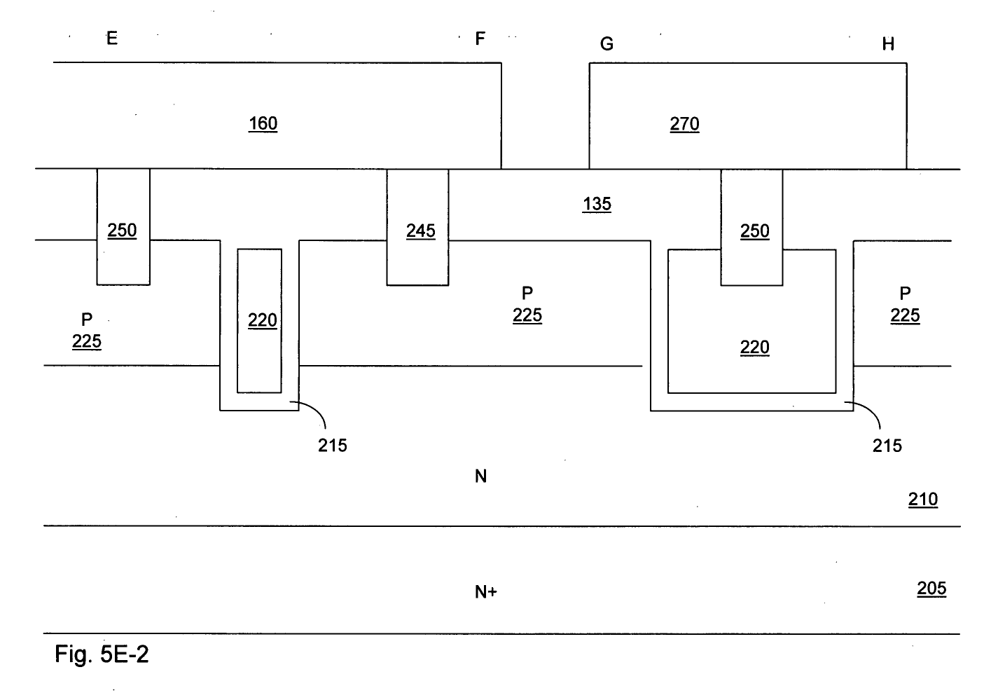

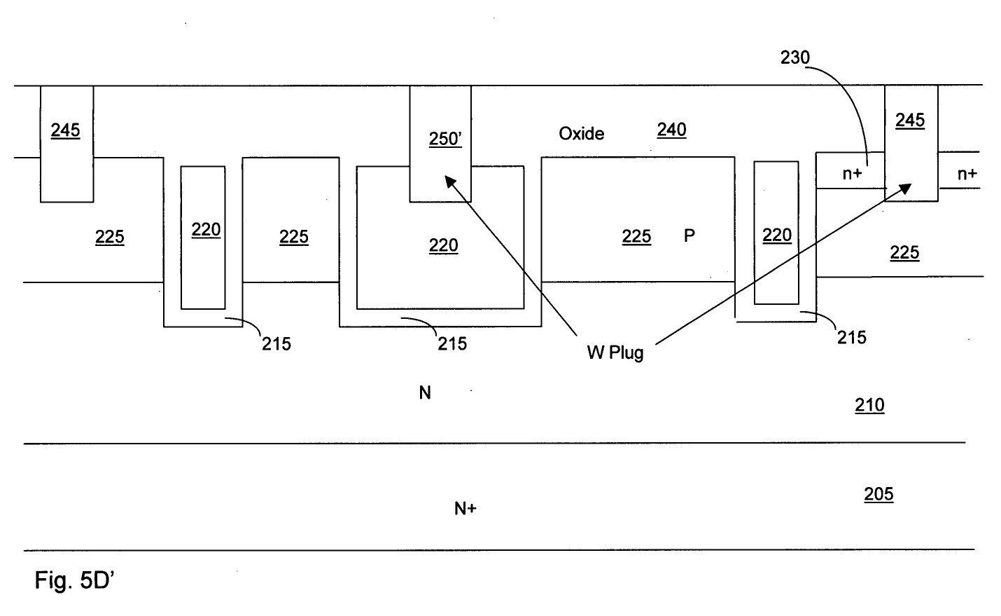

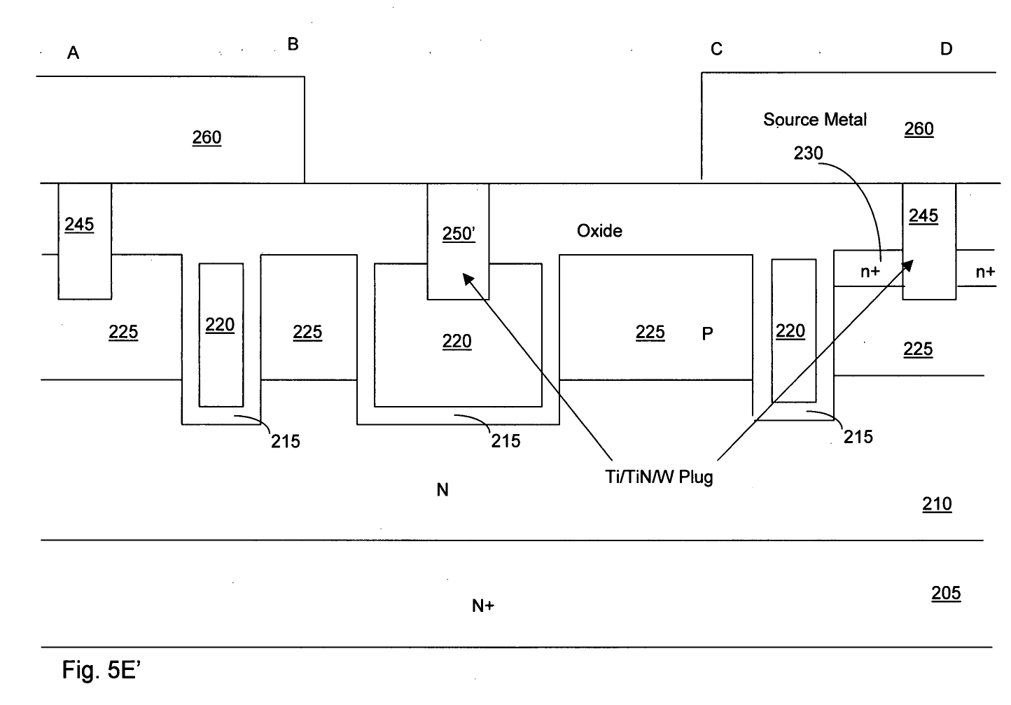

Referring to FIGS. 5A to 5E for a serial of side cross sectional views to illustrate the fabrication steps of a MOSFET device as that shown in FIGS. 2A to 2D. In FIG. 5A, a trench mask (not shown) is applied to open a plurality of trenches 208 in an epitaxial layer 210 supported on a substrate 205. An oxidation process is performed to form an oxide layer covering the trench walls. The trench is oxidized with a sacrificial oxide to remove the plasma damaged silicon layer during the process of opening the trench. Then an oxide layer 215 is formed followed by depositing a polysilicon layer 220 to fill the trench and covering the top surface and then doped with an N+ dopant. The polysilicon layer 220 is etched back followed by a P-body implant with a P-type dopant. Then an elevated temperature is applied to diffuse the P-body 225 into the epitaxial layer 210. In FIG. 5C, a source mask 228 is applied followed by a source implant with a N-type dopant. Then an elevated temperature is applied to diffusion the source regions 230. In FIGS. 5D-1 and 5D2, a non-doped oxide (NSG) layer and a BPSG layer 240 are deposited on the top surface. A contact mask is applied to carry out a contact etch to open the contact openings by applying an oxide etch through the BPSG and NSG layers 240 followed by a silicon etch to open the contact openings further deeper into the source regions 230 and the body regions 225 and also the gate runner trench 220 as shown in FIG. 5D-2. The MOSFET device thus includes a source-body contact trench and gate-runner plug trench that has an oxide trench formed by first applying an oxide-etch through the oxide layers, e.g., the BPSG and NSG layers. The source-body contact trench and the gate-runner plug trench further include a silicon trench formed by applying a silicon-etch following the oxide-etch. The oxide etch and silicon etch may be a dry oxide and silicon etch whereby a critical dimension (CD) of the source-body contact trench is better controlled. The source-body contact trench and the gate-runner plug trench are then filled with a Ti/TiN/W layer 245 and 250 respectively. In FIGS. 5E-1 and 5E-2, a low resistance metal layer 260 is deposited over the top surface. The low resistance metal layer may be composed of Ti/AlCu or Ti/TiN/AlCu to assure good electric contact is established followed by a metal etch to pattern the metal layer into a source metal pad 260 and a gate metal pads 270 in electrical contact with the source-body trench-plug 245 and the gate-runner trench plug 250 respectively. Referring further to FIG. 5D′ for an alternate contact trench opening process to open the gate-runner contact trench 250′ in the active area followed by forming the source metal pads 260 and the gate metal pads 270 as shown in FIG. 5E′ to manufacture the alternate preferred embodiments as that shown in FIGS. 3 and 4.

A trenched semiconductor device disposed on a substrate is disclosed in this invention that includes a buried trench-poly gate runner electrically contacting to a trenched gate of the trenched semiconductor device and buried under an insulation layer for functioning as a gate runner to increase a gate transmission area contact area to a gate contact metal for reducing gate resistance. In a preferred embodiment, the buried trench-poly gate runner having a greater width than the trenched gate. In a preferred embodiment, a portion of the buried trench-poly gate runner having a substantially same width as the trenched gate. In a preferred embodiment, the semiconductor device further includes a gate contact trench opened in the insulation layer and a doped polysilicon layer disposed in the buried trench gate runner and filled with a contact metal plug therein. In a preferred embodiment, the contact metal plug further comprising a Ti/TiN barrier layer surrounding a tungsten core as a gate contact metal plug. In a preferred embodiment, the semiconductor device further includes a source metal covering a top surface of the trenched semiconductor device wherein the source metal further having a source metal opening disposed in an area above a gate contact plug filled in the gate contact trench opened through the insulation layer.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A trenched metal oxide semiconductor field effect transistor (MOSFET) device comprising a trenched gate surrounded by a source region encompassed in a body region above a drain region disposed on a bottom surface of a substrate, wherein said MOSFET cell further comprising:
a buried trench-poly gate runner electrically contacting to said trench gate buried under an insulation layer for functioning as a gate runner to connected to a gate metal pad through a gate contact plug disposed in a gate contact trench opened through said insulation layer.

2. The MOSFET device of claim 1 wherein:
said buried trench-poly gate runner having a greater width than said trenched gate.

3. The MOSFET device of claim 1 wherein:
a portion of said buried trench-poly gate runner having a substantially same width as said trenched gate.

4. The MOSFET device of claim 1 wherein:
said gate contact trench opened in said insulation layer further extending into a doped poly silicon disposed in said buried trench-poly gate-runner wherein said gate contact trench is further filled with a gate contact metal plug.

5. The MOSFET device of claim 4 wherein:
the contact metal plug further comprising a Ti/TiN barrier layer surrounding a tungsten core as a gate contact metal plug.

6. The MOSFET device of claim 4 further comprising:
a low resistance conductive layer covering a top surface over said gate contact metal plug for further reducing a gate resistance.

7. The MOSFET device of claim 1 further comprising:
a source metal covering a top surface of said MOSFET wherein said source metal further having a source metal opening disposed in an area of an active-area gate contact plug filled in said a gate contact trench opened through said insulation layer.

8. The MOSFET device of claim 1 further comprising:
a source-body contact trench opened through said insulation layer into said source and body regions and filled with a source-body contact metal plug.

9. The MOSFET device of claim 8 wherein:
the source-body contact metal plug further comprising a Ti/TiN barrier layer surrounding a tungsten core as a source-body contact metal.

10. The MOSFET device of claim 5 further comprising:
a thin resistance-reduction conductive layer disposed on a top surface covering said insulation layer and contacting said gate contact metal plug and source-body contact plug whereby said resistance-reduction conductive layer having a greater area than a top surface of said gate contact metal plug and said source-body contact metal plug for reducing said gate resistance and a source-body resistance.

11. The MOSFET device of claim 8 wherein:
said gate and said source-body contact metal plugs filled in said gate contact trench and said source-body contact trench comprising a substantially cylindrical shaped plug.

12. The MOSFET device of claim 1 wherein:
said MOSFET device further comprising a N-channel MOSFET device.

13. The MOSFET device of claim 1 wherein:
said MOSFET device further comprising a P-channel MOSFET device.

14. The MOSFET device of claim 8 wherein:
the source body contact trench and said gate contact trench further comprising an oxide trench formed by an oxide-etch through an oxide layer covering a top surface said MOSFET device.

15. The MOSFET device of claim 8 wherein:
the source body contact trench and said gate contact trench further comprising a silicon trench formed by a silicon-etch after an oxides etch for extending said source-body contract trench into a silicon substrate and extending said gate contact trench to said buried trench-poly gate runner.

16. The MOSFET device of claim 8 wherein:
the source body contact trench and said gate contact trench further comprising a trench opened by a dry oxide and silicon etch whereby a critical dimension (CD) of said source-body contact trench and said gate contact trench is better controlled.

17. The MOSFET device of claim 8 wherein:
the source body contact trench further comprising a trench opened by a dry oxide and silicon etch followed by a wet oxide layer to form irregular shaped trench sidewalls.

18. The MOSFET device of claim 10 wherein:
said thin resistance-reduction conductive layer comprising a titanium (Ti) layer.

19. The MOSFET device of claim 10 wherein:
said thin resistance-reduction conductive layer comprising a titanium nitride (TiN) layer.

20. A trenched semiconductor device disposed on a substrate comprising:
a buried trench-poly gate runner electrically contacting to a trenched gate of said trenched semiconductor device and buried under an insulation layer for functioning as a gate runner to increase a gate transmission area contact area to a gate contact metal for reducing gate resistance.

21. The trenched semiconductor device of claim 20 wherein:
said buried trench-poly gate runner having a greater width than said trenched gate.

22. The trenched semiconductor device of claim 20 wherein:
a portion of said buried trench-poly gate runner having a substantially same width as said trenched gate.

23. The trenched semiconductor device of claim 20 further comprising:
a gate contact trench opened in said insulation layer and a doped polysilicon layer disposed in said buried trench gate runner and filled with a contact metal plug therein.

24. The trenched semiconductor device of claim 23 wherein:
the contact metal plug further comprising a Ti/TiN barrier layer surrounding a tungsten core as a gate contact metal plug.

25. The trenched semiconductor device of claim 20 further comprising:
a source metal covering a top surface of said trenched semiconductor device wherein said source metal further having a source metal opening disposed in an area above a gate contact plug filled in said gate contact trench opened through said insulation layer.

26. A method for manufacturing a trenched metal oxide semiconductor field effect transistor (MOSFET) device comprising a step of forming said MOSFET cell with a trenched gate surrounded by a source region encompassed in a body region above a drain region disposed on a bottom surface of a substrate, the method further comprising:
opening a buried trench-poly gate runner electrically contacting to said trench gate and covering said buried trench-poly gate-runner under an insulation layer for functioning as a gate runner.

27. The method of claim 26 further comprising:
covering said MOSFET device with an insulation layer and applying a contact mask for opening a gate contact trench and opening a source-body contact trench into said source and body regions.

28. The method of claim 27 further comprising:
filling said gate contact trench and said source-body contact trench with contact metal plugs.

29. The method of claim 28 wherein:
said step of filling said gate contact trench and said source-body contact trench with contact metal plug further comprising a step of filling said contact trenches with a Ti/TiN barrier layer surrounding a tungsten core as a contact metal plug.

30. A method for manufacturing a trenched semiconductor device on a substrate comprising:
opening a buried trench-poly gate runner electrically contacting to a trench gate of said trenched semiconductor device for functioning as a gate runner and covering said buried trench-poly gate runner under an insulation layer.

31. The method of claim 30 further comprising:
opening a gate contact trench in said insulation layer and said gate contact trench with a contact metal plug.

32. The method of claim 31 wherein:
said step of filling said gate contact trench with a contact metal plug further comprising a step of filling said trench with a contact metal plug comprising a Ti/TiN barrier layer surrounding a tungsten core as a gate contact metal plug.

33. The method of claim 32 further comprising:
covering a top surface of said trenched semiconductor device with a source metal with a source metal opening opened in an area above a gate contact plug filled in said gate contact trench opened through said insulation layer.
